(19) United States
(12) Patent Application Publication
(10) Pub. No.: US 2013/0222980 A1
(43) Pub. Date: Aug. 29, 2013

(54) CUSTOMIZED FLAT TELEVISION SKIN

(71) Applicants: Stephen Rideout, Hampton, NH (US); Kelli Kane, Hampton, NH (US)

(72) Inventors: Stephen Rideout, Hampton, NH (US); Kelli Kane, Hampton, NH (US)

(21) Appl. No.: 13/405,215

(22) Filed: Feb. 24, 2012

(51) Int. Cl. H05K 5/02

(52) U.S. Cl. 361/679.01

(57) ABSTRACT

The present invention is a customized flat television skin to cover and protect a flat television screen television that includes a polypropylene cover that includes a protective perimeter frame that has a top and a front facing and a protective sheet portion, a plurality of vent cutouts that are disposed on the top of the protective perimeter frame and a plurality of television control cutouts that are disposed on the top of the protective perimeter frame. The customized flat television skin also includes a plurality of input and output control cutouts that are disposed on the top of the protective perimeter frame and a flat television base stand that is attached to a bottom of the flat television being protected by the customized television skin.

### TECHNICAL FIELD & BACKGROUND

Current covers and skins on the market are limited to products such as computers, MP3 players, video game consoles or phones. The lack of skins available for protecting flat televisions leave the product casing of the flat television vulnerable to damage.

The present invention generally relates to a decorative skin. More specifically, the invention is a customized flat television skin.

It is an object of the invention is to provide a customized flat television skin that protects a flat television screen and television frame from dust, dents and scratches.

It is an object of the invention to provide a customized flat television skin that is made of stretchable and washable material to be relatively easy to apply and place onto a flat television screen.

It is an object of the invention to provide a customized flat television skin that provides access to functional buttons and controls of the flat television being protected by the customized flat television skin.

What is really needed is a customized flat television skin that protects a flat television screen and television frame from dust, dents and scratches that is made of stretchable and washable material to be relatively easy to apply and place onto a flat television that provides access to functional buttons and controls of the flat television being protected by the customized flat television skin.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates a front view of a customized flat television skin, according to an embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is utilized repeatedly. The phrase generally does not refer to the same embodiment, however, it may. The terms “comprising”, “having” and “including” are synonymous, unless the context dictates otherwise.

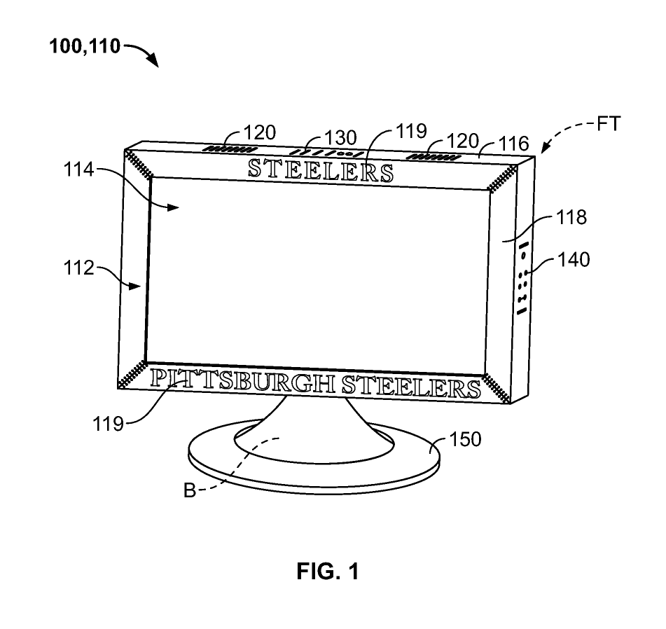

FIG. 1 illustrates a front view of a customized flat television skin 100, according to an embodiment of the present invention.

The customized flat television skin 100 includes a polypropylene cover 110, a plurality of vent cutouts 120, a plurality of television control cutouts 130, a plurality of input and output control cutouts 140 and a flat television base stand 150. The polypropylene cover 110 includes a protective perimeter frame 112 and a protective sheet portion 114. The polypropylene cover 110 is stretchable and washable and is stretched and fit over any suitably sized flat television FT. The protective perimeter frame 112 has a top 116 and a front facing 118 and is approximately 2 mms in thickness. The front facing 118 can display one or more indicia of a user's favorite sport team indicia 119, musical groups or bands, video characters, personalized user indicia or other suitable indicia. The front facing 118 and sports team 119 being illustrated in FIG. 1 is the Pittsburgh Steelers, however any suitable sports team can be displayed. The vent cutouts 120 are disposed on the top 116 of the protective perimeter frame 112 and are positioned over the vents provided on the flat television FT being protected by the customized television skin 100. The television control cutouts 130 are disposed on the top 116 of the protective perimeter frame 112 and are positioned over the television controls such as a volume control and an on and off switch provided on a flat television FT being protected by the customized television skin 100. The input and output control cutouts 140 are positioned over the input and output jacks for supplemental accessories that a user may want to use in combination with the flat television FT being protected by the customized flat television skin 100 are disposed on the top 116 of the protective perimeter frame 112 and are positioned over the input and output control jacks provided on a flat television FT being protected by the customized flat television skin 100. The flat television base stand 150 is typically attached to a bottom B of the flat television FT being protected by the customized television skin 100 and raises and stabilizes the flat television FT being protected by the customized flat television skin 100 and can be any type of suitable flat television base stand 150.

The customized flat television skin is a personalized, approximately two millimeter wide polypropylene fabric designed to cover flat televisions. The cover is stretchable, and pulls over the four corners of a flat television for a tight fit. The customized flat television skin is customizable, allowing for prints such as sports teams, bands, video game characters, and a user's personal images. The customized flat television skin will be readily available in a variety of sizes to fit all flat screen televisions, such as liquid crystal display, plasma, and digital light projection televisions. The customized flat television skin features a polypropylene fabric that protects the flat television's casing from dust and scratches. The customized flat television skin allows for washing, leaving the personalized image vivid and colorful.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

1. A customized flat television skin to cover and protect a flat television screen television, comprises:
a polypropylene cover that includes a protective perimeter frame that has a top and a front facing and a protective sheet portion;
a plurality of vent cutouts that is disposed on said top of said protective perimeter frame;
a plurality of television control cutouts that are disposed on said top of said protective perimeter frame;
a plurality of input and output control cutouts that are disposed on said top of said protective perimeter frame; and
a flat television base stand is attached to a bottom of said flat television being protected by said customized television skin.

2. The customized flat television skin according to claim 1, wherein said polypropylene cover is stretchable and is stretched and fit over said flat screen television.

3. The customized flat television skin according to claim 2, wherein said polypropylene cover is washable.

4. The customized flat television skin according to claim 1, wherein said front facing displays one or more indicia of a user's favorite sport team indicia.

5. The customized flat television skin according to claim 1, wherein said vent cutouts and are positioned over one or more vents provided on said flat television being protected by said customized television skin.

6. The customized flat television skin according to claim 1, wherein said television control cutouts are positioned over said flat television controls provided on said flat television being protected by said customized television skin.

7. The customized flat television skin according to claim 6, wherein said flat television controls include a volume control and an on and off switch.

8. The customized flat television skin according to claim 1, wherein said input and output control cutouts are positioned over said input and output control jacks provided on said flat television being protected by said customized flat television skin.

9. The customized flat television skin according to claim 8, wherein said input and output control cutouts that are positioned over said input and output jacks utilized with supplemental accessories that said user uses in combination with said flat television being protected by said customized flat television skin.

10. The customized flat television skin according to claim 1, wherein said flat television base stand raises and stabilizes said flat television being protected by said customized flat television skin.

11. A customized flat television skin to cover and protect a flat television screen television, comprises:
a washable and stretchable polypropylene cover that includes a protective perimeter frame that has a top and a front facing and a protective sheet portion;
a plurality of vent cutouts that is disposed on said top of said protective perimeter frame;
a plurality of television control cutouts that are disposed on said top of said protective perimeter frame;
a plurality of input and output control cutouts that are disposed on said top of said protective perimeter frame; and
a flat television base stand is attached to a bottom of said flat television being protected by said customized television skin and raises and stabilizes said flat television being protected by said customized flat television skin.

12. The customized flat television skin according to claim 11, wherein said polypropylene cover is stretched and fit over said flat screen television.

13. The customized flat television skin according to claim 11, wherein said front facing displays one or more indicia of a user's favorite sport team indicia.

14. The customized flat television skin according to claim 11, wherein said vent cutouts and are positioned over one or more vents provided on said flat television being protected by said customized television skin.

15. The customized flat television skin according to claim 11, wherein said television control cutouts are positioned over said flat television controls provided on said flat television being protected by said customized television skin.

16. The customized flat television skin according to claim 15, wherein said flat television controls include a volume control and an on and off switch.

17. The customized flat television skin according to claim 11, wherein said input and output control cutouts are positioned over said input and output control jacks provided on said flat television being protected by said customized flat television skin.

18. The customized flat television skin according to claim 17, wherein said input and output control cutouts that are positioned over said input and output jacks utilized with supplemental accessories that said user uses in combination with said flat television being protected by said customized flat television skin.

19. The customized flat television skin according to claim 11, wherein said protective perimeter frame is approximately 2 mms in thickness.

20. The customized flat television skin according to claim 11, wherein said flat television screen is selected from the group consisting of a liquid crystal display television screen, a flat plasma television screen or a digital light projection television screen.
